(19) United States
(12) Patent Application Publication
(10) Pub. No.: US 2023/0265560 A1
(43) Pub. Date: Aug. 24, 2023

(54) PUMPING LINER AND METHODS OF MANUFACTURE AND USE THEREOF

(71) Applicant: Applied Materials, Inc., Santa Clara, CA (US)

(72) Inventors: Badri Narayan Ramamurthi, Los Gatos, CA (US); Viren Sunil Kalsekar, Sunnyvale, CA (US); Vinay K. Prabhakar, Fremont, CA (US)

(21) Appl. No.: 18/102,861

(22) Filed: Jan. 30, 2023

Related U.S. Application Data
(60) Provisional application No. 63/313,111, filed on Feb. 23, 2022.

(51) Int. Cl. C23C 16/455; C23C 16/458

(52) U.S. Cl. CPC C23C 16/45591; C23C 16/458

(57) ABSTRACT

Disclosed herein is a pumping liner, having a gas inlet configured to receive a process gas; openings in communication with the gas inlet, the openings configured to surround a substrate support and to direct the process gas onto the substrate support. At least a portion of the openings each has a different size. Each of the openings is configured to provide a gas mass flow rate that is within ±5% of a target gas mass flow rate. The pumping liner further includes a gas outlet configured to receive unreacted process gas and reacted process gas byproducts.

### CLAIM OF PRIORITY

The present application claims the benefit under 35 U.S.C. § 119(e) of U.S. Provisional Patent Application No. 63/313,111 filed Feb. 23, 2023, which is incorporated by reference herein.

### FIELD

The present disclosure relates to electronic device manufacturing, and more specifically to one or more embodiments of a pumping liner for electronic device manufacturing equipment and methods of manufacture and use thereof.

### BACKGROUND

Electronic device manufacturing equipment typically includes one or more process chambers having a substrate support on which a substrate is seated during processing. In some processes, a pressurized gas is introduced above the substrate and flows out radially and downward onto the substrate to deposit a film. A pumping liner may be used to direct gas flow onto the substrate's surface. Conventional pumping liners are designed with uniform hole sizes, and baffles are used to empirically tune on-substrate deposition uniformity. The baffles provide flow obstruction to reduce or prevent significant pressure changes across the holes of one site as compared to the holes of another site. Such conventional pumping liners are difficult to optimize because there are numerous degrees of freedom (e.g., the number of baffles, the distance between the baffles and the pumping hole, the angular size of the baffles, etc.). Because the tuning process is empirical, every time the configuration is optimized, a new part is tested. This tuning process is time-consuming, and space constraints often limit the use of baffles. Accordingly, pumping liners inevitably have some regions that deliver more gas to the substrate than other regions, resulting in non-uniform gas delivery to processed substrates.

### BRIEF SUMMARY

Disclosed herein are various embodiments of a pumping liner for a process chamber, comprising: a main body configured to surround a substrate support of the process chamber, the main body comprising: a plurality of openings configured to surround the substrate support and to receive at least one of unreacted process gas or reacted gas products that originate from a process gas delivered toward the substrate support, wherein one or more first openings of the plurality of openings have a first size that is different from a second size of one or more second openings of the plurality of openings, and wherein each of the plurality of openings is configured to provide a gas mass flow rate that is within ±5% of a target gas mass flow rate; and a gas outlet configured to evacuate from the pumping liner at least one of the unreacted process gas or the reacted process gas byproducts received via the plurality of openings.

According to various embodiments, further disclosed herein is a semiconductor process chamber, comprising: a substrate support to support a substrate; a faceplate to deliver a process gas to the substrate; and a pumping liner, arranged about the substrate support, the pumping liner comprising: a plurality of openings configured to surround the substrate support and to receive at least one of unreacted process gas or reacted gas products that originate from the process gas delivered toward the substrate support, wherein one or more first openings of the plurality of openings have a first size that is different from a second size of one or more second openings of the plurality of openings, and wherein each of the plurality of openings is configured to provide a gas mass flow rate that is within ±5% of a target gas mass flow rate; and a gas outlet configured to evacuate from the pumping liner at least one of the unreacted process gas or the reacted process gas byproducts received via the plurality of openings.

In yet further embodiments, disclosed herein is a method of manufacturing a variable size opening pumping liner, comprising: forming a main body of the pumping liner; and forming a plurality of openings in the main body, wherein the plurality of openings configured to surround the substrate support and to receive at least one of unreacted process gas or reacted gas products that originate from a process gas delivered toward the substrate support, wherein one or more first openings of the plurality of openings have a first size that is different from a second size of one or more second openings of the plurality of openings, and wherein each of the plurality of openings is configured to provide a gas mass flow rate that is within ±5% of a target gas mass flow rate; and a gas outlet configured to evacuate from the pumping liner at least one of the unreacted process gas or the reacted process gas byproducts received via the plurality of openings.

### BRIEF DESCRIPTION OF THE DRAWINGS

The drawings, described below, are for illustrative purposes and are not necessarily drawn to scale. The drawings are not intended to limit the scope of the disclosure in any way.

FIG. 1A illustrates an electronic device manufacturing apparatus having a variable size opening pumping liner in accordance with one or more embodiments disclosed herein.

FIG. 1B illustrates a variable size opening pumping liner in an electronic device manufacturing apparatus in accordance with one or more embodiments disclosed herein.

FIG. 1C is a sectional view of a variable size opening pumping liner in an electronic device manufacturing apparatus in accordance with one or more embodiments disclosed herein.

FIG. 2 illustrates the flow domain within a variable size opening pumping liner in accordance with one or more embodiments disclosed herein.

FIG. 3 is a chart showing an exemplary mass flow distribution (i.e., mass flow as a function of opening number) of gas flowing through the openings of a variable size opening pumping liner in accordance with one or more embodiments disclosed herein.

FIG. 4 is a chart showing an exemplary opening size (e.g., diameter in mils) as a function of opening number for a variable size opening pumping liner in accordance with one or more embodiments disclosed herein.

FIG. 5 is a chart showing an exemplary hole size distribution (deviation from best known method or “BKM” as a function of hole number) for a variable size opening pumping liner in accordance with one or more embodiments disclosed herein.

FIG. 6 is a chart showing exemplary hole size distributions (hole diameter deviation from BKM as a function of hole number) for variable size opening pumping liners in accordance with one or more embodiments disclosed herein.

FIG. 7 illustrates a method of manufacturing a variable size opening pumping liner according to one or more embodiments herein.

### DETAILED DESCRIPTION

Reference will now be made in detail to the example embodiments of this disclosure, which are illustrated in the accompanying drawings. Wherever possible, the same reference numbers will be used throughout the drawings to refer to the same or like parts throughout the several views. Features of the various embodiments described herein may be combined with each other, unless specifically noted otherwise.

Pumping liners, according to one or more embodiments herein, are liners configured to be disposed around a substrate support. Pumping liners are used to distribute gas flow across the surface of a substrate seated on the substrate support during processing. In embodiments set forth herein, pumping liners include a plurality of openings of different sizes, which reduces or eliminates the use of baffles. By varying the gas inlet opening sizes throughout the pumping liner, a uniform radial flow distribution of gas above a substrate can be maintained during processing, even in the absence of baffles. Pumping liners described in embodiments herein provide improved gas flow rate uniformity than conventional pumping liners. Further, reducing or eliminating the baffles correspondingly reduces the size or footprint of the pumping liner, which can ultimately reduce an overall size of a process chamber.

Pumping liners according to one or more embodiments herein can have a universal design configured to meet the space constraints within a variety of different equipment (e.g., a process chamber). Alternatively, pumping liners can be configured for particular applications and/or process chambers. Pumping liners as described herein also are manufactured and tuned in fewer design iterations than conventional pumping liners, which typically use baffles and they can be optimized without the need for baffles.

Pumping liners in embodiments may have an optimized opening size distribution. In some embodiments, openings of the pumping liners are clustered in groups. The openings in each group can have the same size as other openings in the group. The use of groups with common opening sizes may increase ease of manufacturability by setting opening sizes based on different drill bit sizes. The number of openings in each group and/or number of groups can be selected to meet specifications for flow uniformity and manufacturability.

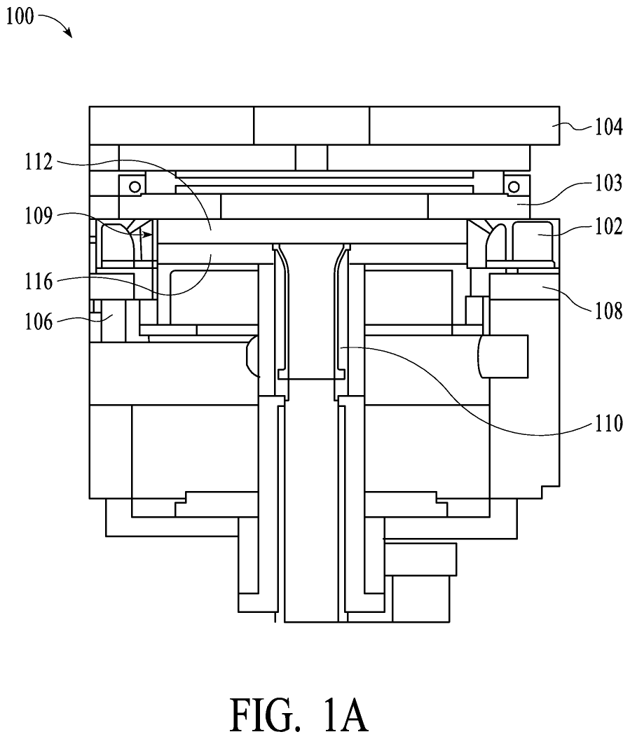

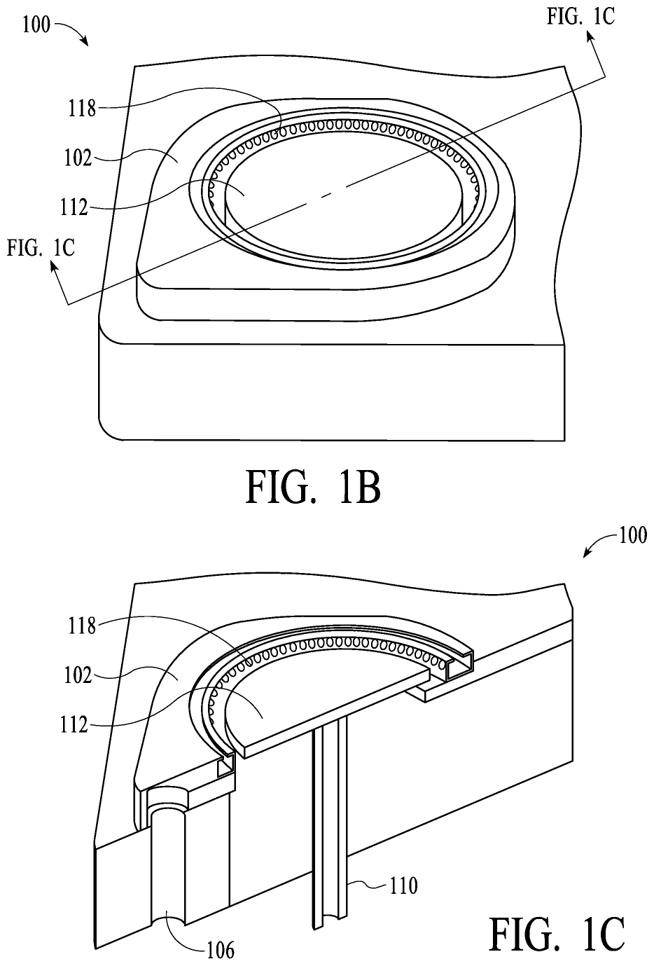

FIGS. 1A-1C illustrate an electronic device manufacturing apparatus 100 having a variable size opening pumping liner 102 in accordance with one or more embodiments disclosed herein. Suitable electronic device manufacturing apparatuses include, but are not limited to, physical vapor deposition (PVD) chambers, atomic layer deposition (ALD) chambers, chemical vapor deposition (CVD) chambers, and so on. The apparatus as shown in FIG. 1A, includes an upper lid 104 and a lower lid 108 configured to seal and unseal an interior of chamber 106 from an external environment. In some manufacturing processes, the interior of chamber 106 is evacuated, for example, by a vacuum pump to achieve vacuum conditions such as ultra-high vacuum conditions. Upper lid 104 and lower lid 108 may provide a hermetic seal of the interior of chamber 106 to maintain vacuum conditions.

Apparatus 100 further includes a substrate support assembly 109. The substrate support assembly 109 holds a substrate (not shown) during processing. In one embodiment, the substrate support assembly includes a shaft or pedestal 110 attached to a substrate support 112. In one embodiment, the substrate support is or includes a chuck, such as an electrostatic chuck, a vacuum chuck, or other type of chuck. The chuck may include one or more heating elements. In one embodiment, the substrate support 112 is a heater. In one embodiment, substrate support assembly 109 includes an isolator (e.g., a ceramic isolator) 116 positioned about the shaft 110 and beneath the substrate support 112. As shown in FIG. 1A, a pumping liner 102 may be arranged around substrate support 112 and ceramic isolator 116 and beneath a faceplate 103. A substrate may be positioned on the substrate support 112 for processing. Substrate support 112 (e.g., heater or chuck with heating element) may be configured to control the temperature of a substrate during processing.

The faceplate 103 can be comprised of holes having a pyramidal, conical, or other similar shape with a narrow top portion expanding to a wide bottom portion. The faceplate 103 may additionally be flat as shown and may include multiple apertures used to distribute process gases. The faceplate 103 may deliver process gases onto a substrate. In some embodiments, plasma generating gases and/or plasma excited species may pass through apertures in faceplate 103 for uniform delivery to a volume above the substrate. The faceplate 103 also allows plasma generated radicals to pass through it when cleaning the chamber.

Electronic device manufacturing apparatus 100 may include a gas panel (not shown) to provide process and/or cleaning gases to the chamber 106 through a gas distribution assembly (not shown). Examples of processing gases may be used to process in the processing chamber including halogen-containing gas, such as C₂F₆, SF₆, SiCl₄, HBr, NF₃, CF₄, CHF₃, CH₂F₃, Cl₂ and SiF₄, among others, and other gases such as O₂, or N₂O. Examples of other gases (e.g., such as carrier gases) that may be flowed include N₂, He, Ar, and other gases inert to process gases (e.g., non-reactive gases). The gas distribution assembly may have one or multiple apertures to deliver gases to pumping liner 102.

The substrate may be seated on substrate support 112 when gas is introduced from variable size opening pumping liner 102 into chamber 106 and onto the substrate. The variable size opening pumping liner 102 may include a plenum having a gas inlet, multiple openings, optionally one or more baffles, and a gas outlet.

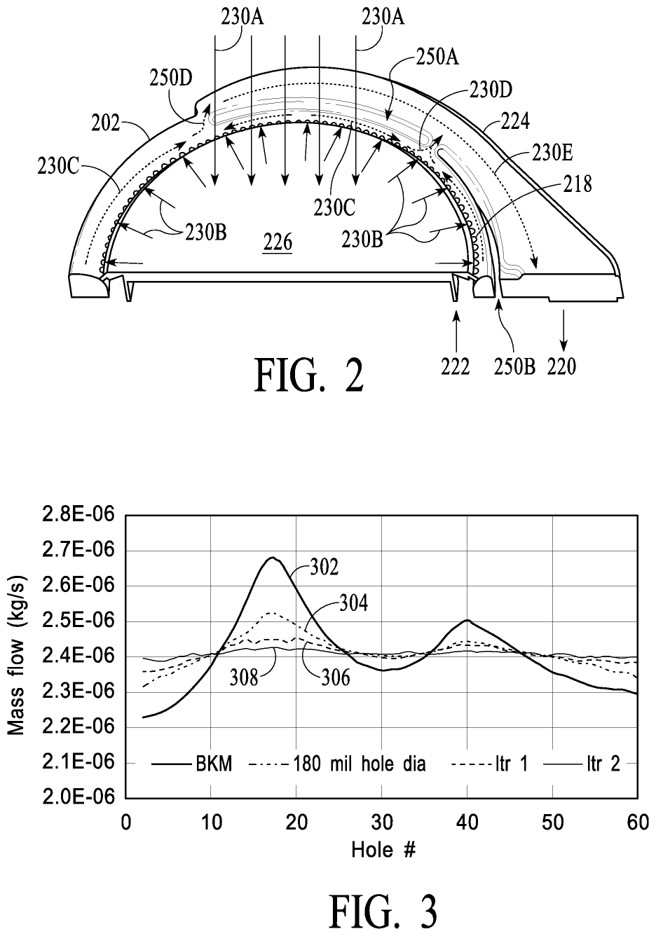

Referring to FIGS. 1A and 1B, gas flows into the pumping liner 102 via a gas inlet, and from the pumping liner 102 into the chamber 106 through openings 118 of pumping liner 102. In embodiments, the gas flows radially across the surface of the substrate toward its center and exits through an outlet, via a plenum (see FIG. 2). According to one or more embodiments, a size of openings 118 varies about the perimeter of pumping liner 102 and substrate support 112 in order to provide a uniform mass flow rate of gasses (e.g., process gasses) through the openings 118. The size of each of the openings 118 is designed so as to provide about the same or substantially the same target mass flow rate through each of the openings. Gas flow rate is generally higher near the gas outlet of the plenum. Accordingly, in order to increase the gas flow rate of openings that are not close to the gas outlet, the size of such openings may increase with distance from the gas outlet. In an example, the mass flow rate of a first opening having a minimum gas flow rate among the openings of the plurality of openings is within about ±5%, about ±4%, about ±3%, about ±2%, about ±1%, about ±0.5% of the mass flow rate of a second opening of the plurality of openings having a maximum gas flow rate among the openings of the plurality of openings. In some embodiments, the mass flow rate through each of the openings is substantially uniform or within about ±5%, about ±4%, about ±3%, about ±2%, about ±1%, about ±0.5% of each other. In some embodiments, each opening has a mass flow rate that is within about ±5%, about ±4%, about ±3%, about ±2%, about ±1%, about ±0.5% of a target gas flow rate. Such gas flow rate uniformity may be achieved by using openings (e.g., holes) with non-uniform sizes across the inner diameter of the plenum.

In some embodiments, the pumping liner 102 may include about 10 openings to about 100 openings, or any individual value or sub-range within this range (e.g., about 20 openings, 30 openings, 40 openings, 50 openings, 60 openings, 70 openings, 80 openings, 90 openings, 120 openings, and so on). The openings 118 may be in any suitable pattern to provide a largely uniform mass flow rate. In some embodiments, the pumping liner 118 is symmetric, and opening sizes and shapes on one half of the pumping liner are mirrored on the other half of the pumping liner. In one or more embodiments, the opening sizes are arranged in groups, and each opening that share a group have a same opening size. For example, openings 1-3 may constitute a first group and all have the same size, openings 4-6 may constitute a second group and all be the same size that is larger than the size of openings 1-3 of the first group, openings 7-9 may constitute a third group and all be the same size that is larger than the sizes of openings 4-6 of the second group, and so on. Openings 118 may be circular, rectangular, square, triangular, and so on.

In some embodiments, the spacing between the openings may be uniform. In other embodiments, the spacing between openings may be non-uniform. According to one or more embodiments, the pumping liner 102 may have fewer openings near an outlet or access point and progressively more openings at locations further away from such elements, although spacing should be optimized to avoid stagnant zones (e.g., between openings) where process gas accumulates and/or where gas flow across the substrate is reduced. Such stagnant zones could result in excess deposition of material and buildup that can ultimately erode or dislodge, resulting in defects (e.g., particle defects) on the substrate. In some embodiments, the variable opening size pattern adds parallel openings on top of existing openings (e.g., uniform openings) spaced vertically from the existing openings to increase the amount of flow rather than having a single opening with a larger diameter.

In some embodiments, the opening sizes and patterns are configured for a particular application. For example, a first pumping liner having a first pattern of openings may be configured for a first application (e.g., deposition of a rare earth oxide at elevated temperature), while a second pumping liner having a second pattern of openings may be configured for a second application (e.g., deposition of an aluminum oxide at low temperature).

In addition to meeting a mass flow rate specifications, considerations for optimizing each opening 118 may include the pressure drop of fluid flowing through one or more openings and/or conductance of the process gas during evacuation. As the opening size (e.g., diameter) decreases, the pressure drop of a fluid flowing through the opening increases. As such, in addition to targeting a mass flow rate, the minimum allowable pressure drop suitable for the particular process also can be taken into consideration in determining opening size (e.g., hole diameter). Another consideration in designing the openings is enabling a pump to quickly exhaust the process gases from the chamber after a process is complete. If the openings are too small, then conductance will decrease, resulting in a longer time to exhaust the chamber, which would decrease throughput of the electronic device manufacturing equipment. In some embodiments, to balance the above considerations of target mass flow rate, pressure drop and conductance, the average size of the openings may be specified for a particular process. In some embodiments, the average opening size of the pumping liner is about 100 mils to about 500 mils, about 150 mils to about 300 mils, or about 180 mils to about 240 mils, or any individual value or sub-range within these ranges.

In embodiments, opening size of the plurality of openings 118 is based on distance from the gas outlet. Opening size may increase with distance from the gas outlet. This is because mass flow rates are generally higher for openings that are near the gas outlet. For example, for two openings of equal size where a first opening is near the gas outlet and a second opening is distant from the gas outlet, the second opening will have a lower mass flow rate than the first opening. Additionally, in some embodiments the pumping liner 102 may include one or more baffles that are configured to act as a flow obstruction. The baffles (not shown) that may limit pressure change across an inner diameter of the pumping liner 102. The baffles may be positioned between openings and the gas outlet on a side of the pumping liner 102.

Where baffles are used, they may cause some openings that are physically close to the gas outlet to actually have a longer flow path to the gas outlet than other openings that are physically more distant from the gas outlet. In such embodiments, opening size may vary based on distance of a gas flow path between the opening and the gas outlet. For example, if a pumping liner 102 has two baffles with a gap between the two baffles that provides first access point to the gas outlet and a space at an edge of one of the baffles that provides a second access point to the gas outlet, then opening size may be based at least in part on the distance from the first and second access points.

Yet a further consideration when designing the opening size pattern is the flow or pressure distribution on the substrate support 112. The size distribution of the openings 118 in the variable size opening pumping liner 102 may be configured to provide a pressure that is as concentric around the center of the substrate support 102 as possible. For example, a pumping liner 102 that results in a bullseye deposition or a deposition of material skewed to one side or another is suboptimal. The sizes of the various openings 118 in the pumping liner 102 should be optimized to provide an even deposition of material on the substrate. Optimizing the opening size pattern to provide an even flow or pressure distribution across the substrate can result in a more even deposition of material onto the substrate.

According to one or more embodiments, pumping liner 102 may be constructed of any suitable material that is preferably inert to the semiconductor process gases used in a particular application. Suitable pumping liner 102 materials include, but are not limited to, aluminum, aluminum 6061, stainless steel or combinations thereof. In some embodiments, the pumping liner 102 is coated with an erosion resistant coating, for example, a thin film coating deposited by plasma enhanced deposition, chemical vapor deposition, atomic layer deposition, ion assisted deposition, anodization or any other suitable deposition method. Such thin film coatings may include a metal oxide, such as aluminum oxide, zirconium oxide, a rare earth metal oxide (e.g., yttrium, erbium, etc.), ytrrium aluminum garnet (YAG), or combinations thereof. In some embodiments, the coating is an atomic layer deposition coating that has a thickness of about 1 nm to about 10 μm on the surface of the pumping liner and optionally on walls of the openings. In some embodiments, the pumping liner 102 is formed of anodized aluminum.

FIG. 2 shows the flow domain (e.g., negative volume) 202 in a portion of a variable size opening pumping liner (e.g., such as variable size opening pumping liner 102 of FIGS. 1A-C) according to one or more embodiments herein. The flow domain is defined by the process chamber having a pumping liner installed therein such that the volume filled by the process gas is shown in FIG. 2. In some embodiments, a pressurized purge gas (e.g., Helium) 222 flows beneath the substrate (not shown) in a space between the pedestal and/or substrate support (not shown) and the substrate. According to at least one embodiment, purge gas 222 flows in the space beneath the substrate to reduce and/or prevent process gases from diffusing beneath the substrate support. If process gases were to diffuse beneath the heater, they could deposit on parts of the electronic device manufacturing system. In some embodiments, the purge gas 222 continuously flows to reduce or avoid back streaming or gas diffusion below the heater.

In one or more embodiments, the arrangement in the process chamber includes a plenum 224 that facilitates circulation of the process gas. The initial flow 230A of process gas may be directed from a faceplate onto a region 226 above the substrate support (e.g., onto a substrate supported by the substrate support. The process gas may then flow 230B through pumping openings 218 and into plenum 224. The gas may flow 230C through plenum 224 and further flow 230E to outlet 220. In some embodiments, the plenum 224 includes one or more baffles (represented via gaps 250A, 250B proximate to the gas outlet 220 to restrict a gas flow near the outlet 220. In such embodiments, the gas may flow 230D through access points provided between and/or at edges of the baffles 250A-B and then flow 230D toward the outlet 220.

During processing, a substrate (not shown) is configured to seat on a substrate support (not shown) in region 226 such that the process gases flow radially from the region 226 through the inlet openings 218 and then through the plenum 224 to outlet 220. In some embodiments, a purge gas 222 (e.g., N₂, Argon, Helium, air, CDA or combinations thereof) is configured to purge the flow domain after process gases are used. In some embodiments, the substrate support has a diameter of about 301 mm to about 400 mm, or any individual size or sub-range within this range, and the substrate has a diameter of about 100 mm to about 320 mm. In some embodiments, the substrate support has a diameter of about 360 mm and the substrate has a diameter of about 300 mm. The size of plenum 224 may be optimized based on size constraints within the process chamber. A larger chamber may provide more space for a larger plenum. In some embodiments, plenum 224 has two outlets. In some embodiments, the plenum 224 has a single outlet 220, as shown.

In some embodiments, the openings closest to the outlet(s) 220 and/or access point(s) to the outlet 220 of the plenum may have a relatively smaller size (i.e., to reduce the mass flow rate) than openings further away from the outlet(s) and/or access point(s) to the outlets. In one or more embodiments, the pattern of opening sizes may be configured based on the location of the outlet in the pumping liner. Placement of the outlet of the pumping liner may impact which openings are smaller or larger than an average opening diameter for the pumping liner. The shape and volume of the pumping liner also may be a consideration when determining the size pattern of openings throughout the liner. In some embodiments, a first half of the openings may have a first size pattern and a second half of the openings may have a second size pattern. For example, the pattern of the openings in the second half can mirror the pattern of the openings in the first half

FIG. 3 is a chart showing an exemplary mass flow distribution (i.e., mass flow as a function of opening number) of gas flowing through the openings of a variable size opening pumping liner in accordance with one or more embodiments disclosed herein as compared to conventional pumping liners. The line indicated as BKM 302 is the mass flow rate as a function of opening number through the openings of a conventional pumping liner having equally sized openings. The mass flow rate distribution of the BKM liner is compared with that of another conventional pumping liner 304 having uniform openings (180 mil in diameter), a first iteration (Itr 1) 306 of a variable size opening pumping liner and a second iteration (Itr 2) 308 of a variable size opening pumping liner. The target mass flow rate for the pumping liners shown in FIG. 3 was about 2.4e⁻⁰⁶. As shown in FIG. 3, the mass flow rate of the BKM pumping liner 302 varied from about 2.23e⁻⁶ kg/s at its lowest level (i.e., opening 1) to about 2.69e⁻⁶ kg/s at its highest level (i.e., opening 17). The variation in mass flow rate across the openings for the 180 mil opening 304 comparative pumping liner, was less than that for the BKM 302 pumping liner as shown in FIG. 3. Variable size opening pumping liners Itr1 306 and Itr2 308, according to embodiments herein, had largely uniform mass flow rates across all of the openings in the pumping liner. For example, the mass flow rate for Itr1 306 varied from about 2.36e⁻⁶ kg/s at opening 1 to about 2.45e⁻⁶ kg/s at opening 20. The variation in mass flow rate across all openings for Itr1 306 as compared to the target was about ±1% or less.

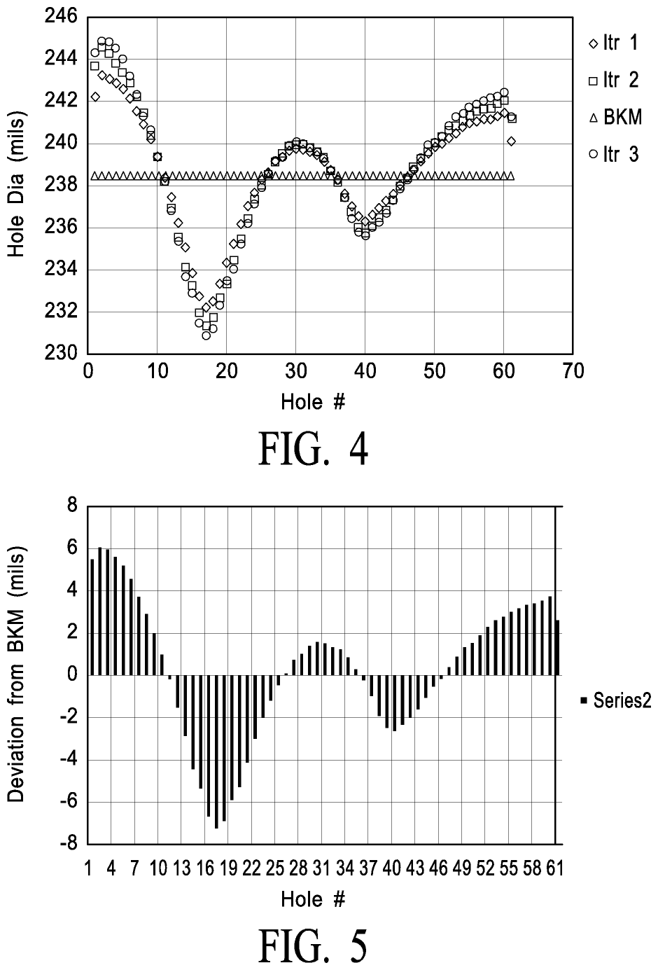

FIG. 4 is a chart showing an exemplary opening diameter (mils) as a function of opening number for a variable size opening pumping liner in accordance with one or more embodiments disclosed herein. The opening size for the comparative BKM pumping liner was constant at about 238.2 mils. The opening sizes for variable size opening pumping liners according to embodiments herein, iteration 1 (Itr 1), iteration 2 (Itr 2) and iteration 3 (Itr 3), varied from about 245 mils to about 231 mils. Itr 1 and Itr 2 correspond to Itr 1 and Itr 2 of FIG. 3, respectively. The outlet of the variable size opening pumping liners Itr 1, Ir 2, Itr 3 was closest to opening 17, which had the smallest opening diameter. Opening 2 was further away from the outlet and had the largest opening diameter. The minimum in opening diameter at opening 40 indicates that there was an access point near this opening. The further peaks in opening diameter at opening 30 and opening 60 indicate that these openings were further away from the outlet and/or access points. By varying the opening diameter throughout the pumping liner, the mass flow rate through each of the openings can be optimized to meet a target mass flow rate. Providing a consistent mass flow rate through each of the openings results in a more uniform distribution of the process gas onto the substrate and consequently more uniform deposition (or etching).

FIG. 5 is a chart showing an exemplary hole size distribution (deviation from BKM as a function of hole number) for a variable size opening pumping liner in accordance with one or more embodiments disclosed herein. As discussed with respect to FIG. 4, the uniform hole size for the BKM comparative pumping liner in the provided example was about 238.2 mils. FIG. 5 shows the positive or negative difference between each of the holes of the conventional BKM pumping liner as compared to each of the holes of a variable size opening pumping liner according to embodiments herein. The hole sizes differed as much as 6 or 7 mils or in other words some of the holes were decreased in size by as much as 7 mils while other holes were increased in size by as much as 6 mils.

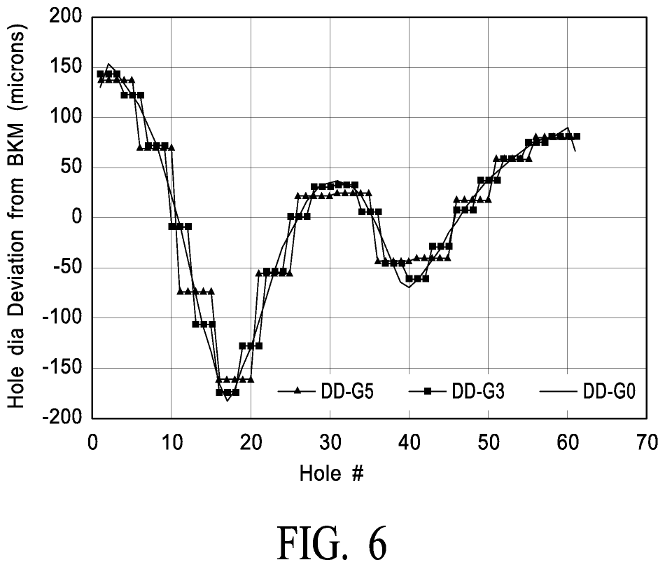

FIG. 6 is a chart showing exemplary hole size distributions (hole diameter deviation from BKM as a function of hole number) for variable size opening pumping liners in accordance with one or more embodiments disclosed herein. Variable size opening pumping liners DD-G5, DD-G3 and DD-GO each were constructed with different hole size patterns. Pumping liner DD-GO was formed with a continuously changing hole size pattern such that the size of each hole gradually increased or decreased with respect to an adjacent hole resulting in the smooth line shown in FIG. 6. In some embodiments, it may be impractical to construct a pumping liner have such a continuously changing hole size pattern. For example, the number of drill bits or punches and/or the drill bit or punch sizes may increase the cost and complexity of manufacturing. According to one or more embodiments, the hole size pattern of the pumping liners can increase or decrease in groups, resulting in fewer drill bits or punches to create the holes. For example, the hole size pattern of pumping liner DD-G3, varied in groups of three (3) such that the average hole size deviation from the comparative BKM pumping liner approximated the transitional hole size pattern of pumping liner DD-GO. The hole size pattern of pumping liner DD-G5 varied in groups of five (5) such that the average hole size deviation from the comparative BKM pumping liner approximated the transitional hole size pattern of pumping liner DD-GO. In one or more embodiments, pumping liners DD-G3 and DD-G5 may have improved manufacturability and a lower cost than a pumping liner having a continuous hole size pattern. Use of groups of openings enables hole sizes to be engineered based on available drill bit sizes.

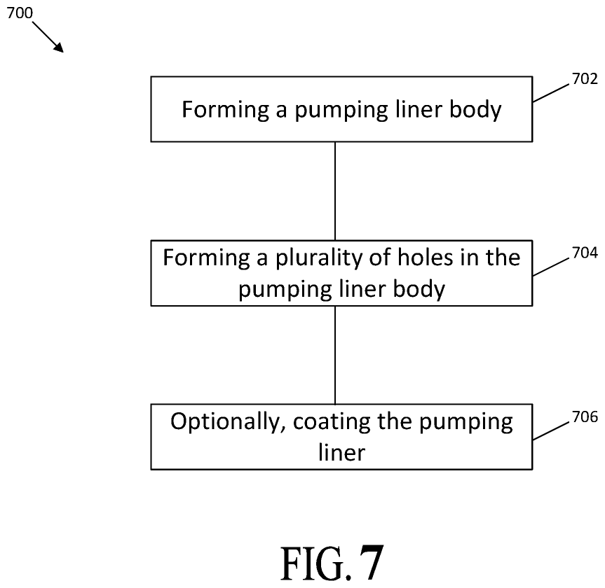

FIG. 7 illustrates a method 700 of manufacturing a variable size opening pumping liner according to one or more embodiments herein. At 702, the method includes forming the main body of a pumping liner suitable for a particular application and/or manufacturing equipment. Forming a pumping liner 702 can be performed by machining, metalworking, metal casting, forging, three-dimensional printing, injection molding, over-molding or combinations thereof. The pumping liner body may be formed of aluminum, aluminum 6061, stainless steel, combinations thereof, or any other suitable erosion resistant metal, polymer or composite.

At 704, method 700 includes forming a plurality of openings in the pumping liner main body. The plurality of openings are of variable size. In some embodiments, a plurality of opening forming tools (e.g., drill bits, punches, etc.) may be used to form the plurality of openings having the optimized variable size pattern. In some embodiments, adjacent openings may be formed with different size opening forming tools. In yet other embodiments, a group of adjacent openings may be formed by the same size opening forming tool. In some embodiments, the variable size openings will be formed concentrically in the pumping liner about the location where a substrate will be seated. Any suitable pattern may be used such as one or more straight lines, staggered lines, a honeycomb, etc.

In some embodiments, forming the plurality of openings in the pumping liner is performed by an automated process. For example, a robot or assembly device may be used to form the openings at the predetermined locations. A robot arm may be configured to rotate or otherwise change drill bit or punch sizes based upon an algorithm in order to create the desired opening size pattern, such as via a computer numerical control (CNC) machine that drills holes according to a digital file with instructions on where to form holes and hole sizes for each hole.

At block 706, the pumping liner optionally can be coated with an erosion resistant coating. For example, a thin film coating may be deposited onto the surface of the pumping liner using plasma-enhanced deposition, chemical vapor deposition, atomic layer deposition, anodization or a combination thereof. In some embodiments, the erosion resistant coating is comprised of a metal oxide. Suitable metal oxides include, but are not limited to, aluminum oxide, zirconium oxide, a rare earth metal oxide (e.g., yttrium oxide, erbium oxide, etc.) or combinations thereof. The erosion resistant coating may have a thickness of about 1 nm to about 10 μm.

The pumping liner resulting from manufacturing process 700 may be installed in suitable electronic device manufacturing equipment. A conventional uniform hole pumping liner provides a mass flow rate variation of about 19%. The term “variation” is understood to mean the maximum mass flow rate and the minimum mass flow rate through each opening relative to the average. A variable size opening pumping liner manufactured using the above process 700 and having a continuous hole size pattern, provides a mass flow rate variation of about 1.6%. A variable size opening pumping liner manufactured using the above process 700 and having a step change hole size pattern (i.e., groups of 3, 4, 5, and so on), provides a mass flow rate variation of about 4.7% (e.g., for three holes) to about 7.7% (e.g., five holes). As such, variable hole size pumping liners according to embodiments herein provide up to a factor of 10, or a factor of 1.5 to a factor of 10, or any individual value or sub-range within these ranges, improvement over conventional pumping liners.

Reference throughout this specification to, for example, “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

As used herein, the singular forms “a,” “an,” and “the” include plural references unless the context clearly indicates otherwise. Thus, for example, reference to “a robot arm” includes a single robot arm as well as more than one robot arm.

As used herein, the term “about” in connection with a measured quantity, refers to the normal variations in that measured quantity as expected by one of ordinary skill in the art in making the measurement and exercising a level of care commensurate with the objective of measurement and the precision of the measuring equipment. In certain embodiments, the term “about” includes the recited number ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Unless otherwise indicated, all parts and percentages are by weight. Weight percent (wt. %), if not otherwise indicated, is based on an entire composition free of any volatiles, that is, based on dry solids content.

The foregoing description discloses example embodiments of the disclosure. Modifications of the above-disclosed assemblies, apparatus, and methods which fall within the scope of the disclosure will be readily apparent to those of ordinary skill in the art. Accordingly, while the present disclosure has been disclosed in connection with example embodiments, it should be understood that other embodiments may fall within the scope of the disclosure, as defined by the following claims.

What is claimed is:

1. A pumping liner for a process chamber, comprising:
a main body configured to surround a substrate support of the process chamber, the main body comprising:
a plurality of openings configured to surround the substrate support and to receive at least one of unreacted process gas or reacted gas products that originate from a process gas delivered toward the substrate support, wherein one or more first openings of the plurality of openings have a first size that is different from a second size of one or more second openings of the plurality of openings, and wherein each of the plurality of openings is configured to provide a gas mass flow rate that is within ±5% of a target gas mass flow rate; and
at least one gas outlet configured to evacuate from the pumping liner at least one of the unreacted process gas or the reacted process gas byproducts received via the plurality of openings.

2. The pumping liner of claim 1, wherein the plurality of openings comprises about 10 openings to about 120 openings.

3. The pumping liner of claim 1, wherein the plurality of openings comprises a plurality of groups of openings, wherein for each group of the plurality of groups of openings, each opening within the group has a same size.

4. The pumping liner of claim 1, wherein each opening of the plurality of openings is circular, rectangular, square, triangular or a combination thereof.

5. The pumping liner of claim 1, wherein the plurality of openings are configured to be uniformly spaced about the perimeter of the substrate support.

6. The pumping liner of claim 1, wherein the plurality of openings are arranged so that there are fewer openings near the gas outlet and more openings further away from the gas outlet.

7. The pumping liner of claim 1, wherein the plurality of openings are arranged to prevent stagnant zones of process gas flow across the substrate support.

8. The pumping liner of claim 1, wherein the plurality of openings are arranged in parallel lines, a honeycomb pattern or a combination thereof.

9. The pumping liner of claim 1, wherein the plurality of openings gradually increase in size from a first point that is proximate to the gas outlet to a second point.

10. The pumping liner of claim 1, wherein the plenum comprises an erosion resistant metal, an erosion resistant polymer, an erosion resistant composite, aluminum, aluminum 6061, stainless steel or combinations thereof.

11. The pumping liner of claim 10, further comprising:
a ceramic coating on the plenum.

12. The pumping liner of claim 1, wherein the plenum further comprises one or more baffles and has one or more access points for the gas outlet, wherein hole size for the plurality of holes increases with distance from the one or more access points.

13. A semiconductor process chamber, comprising:
a substrate support to support a substrate;
a faceplate to deliver a process gas to the substrate; and
a pumping liner, arranged about the substrate support, the pumping liner comprising:
a plurality of openings configured to surround the substrate support and to receive at least one of unreacted process gas or reacted gas products that originate from the process gas delivered toward the substrate support, wherein one or more first openings of the plurality of openings have a first size that is different from a second size of one or more second openings of the plurality of openings, and wherein each of the plurality of openings is configured to provide a gas mass flow rate that is within ±5% of a target gas mass flow rate; and
a gas outlet configured to evacuate from the pumping liner at least one of the unreacted process gas or the reacted process gas byproducts received via the plurality of openings.

14. The process chamber of claim 13, wherein the substrate support comprises a heater.

15. The process chamber of claim 13, further comprising one or more access points to the process chamber, wherein openings closest to at least one of the outlet or the one or more access points are smaller than openings further away from the outlet or one or more access points.

16. A method of manufacturing a variable size opening pumping liner, comprising:
forming a main body of the pumping liner; and
forming a plurality of openings in the main body, wherein the plurality of openings configured to surround the substrate support and to receive at least one of unreacted process gas or reacted gas products that originate from a process gas delivered toward the substrate support, wherein one or more first openings of the plurality of openings have a first size that is different from a second size of one or more second openings of the plurality of openings, and wherein each of the plurality of openings is configured to provide a gas mass flow rate that is within ±5% of a target gas mass flow rate; and
a gas outlet configured to evacuate from the pumping liner at least one of the unreacted process gas or the reacted process gas byproducts received via the plurality of openings.

17. The method of claim 16, wherein forming the main body comprises at least one of machining, metalworking, casting, forging, three-dimensional printing, injection molding or over-molding a material to form the main body.

18. The method of claim 17, wherein the material comprises an erosion resistant metal, an erosion resistant polymer, an erosion resistant composite, aluminum, aluminum 6061, stainless steel or combinations thereof.

19. The method of claim 16, wherein forming the plurality of openings comprises drilling or punching through the main body to form openings having a variable size pattern. In some embodiments, adjacent openings may be formed with different size opening forming tools.

20. The method of claim 16, further comprising coating the main body and openings with an erosion resistant coating.
